(19) United States
(12) Patent Application Publication
(10) Pub. No.: US 2025/0079223 A1
(43) Pub. Date: Mar. 6, 2025

(54) METHODS AND APPARATUS FOR A SUSCEPTOR ASSEMBLY

(71) Applicant: ASM IP Holding B.V., Almere (NL)

(72) Inventors: Shubham Garg, Gilbert, AZ (US); Hang Zhang, Tempe, AZ (US); Todd Robert Dunn, Cave Creek, AZ (US); George B. Jackson, Phoenix, AZ (US)

(21) Appl. No.: 18/817,440

(22) Filed: Aug. 28, 2024

Related U.S. Application Data
(60) Provisional application No. 63/535,658, filed on Aug. 31, 2023.

(51) Int. Cl. H01L 21/683

(52) U.S. Cl. CPC H01L 21/6833

(57) ABSTRACT

Various embodiments of the present technology may provide a susceptor assembly. The susceptor assembly may include a susceptor plate and a cap disposed on a surface of the susceptor plate. The cap may have electrodes embedded within it. The susceptor plate may have heating elements embedded within it. The cap may be separated from the susceptor plate by an air gap formed by a plurality of dielectric spacers. The plurality of dielectric spacers may be sized for minimal contact on the cap.

### CROSS-REFERENCE TO RELATED APPLICATIONS

This application is a nonprovisional of, and claims priority to and the benefit of, U.S. Provisional Patent Application No. 63/535,658, filed Aug. 31, 2023 and entitled “METHODS AND APPARATUS FOR A SUSCEPTOR ASSEMBLY,” which is hereby incorporated by reference herein.

### FIELD OF INVENTION

The present disclosure generally relates to a method and apparatus for a susceptor assembly. More particularly, the present disclosure relates to a susceptor assembly including a susceptor with heating elements and a cap disposed on the susceptor and having electrodes.

### BACKGROUND OF THE TECHNOLOGY

High stress wafers may need to be flattened (i.e., chucked) using electrostatic forces integrated within the susceptor plate. Without chucking of such wafer, undesired film deposition may occur. Conventional susceptors are formed using a ceramic material, such as aluminum nitride. This material, however, are brittle and provide limited temperature tunability. Aluminum nitride also has a very low fracture toughness, making it prone to cracks and fractures due to thermal stress.

### SUMMARY OF THE INVENTION

Various embodiments of the present technology may provide a susceptor assembly. The susceptor assembly may include a susceptor plate and a cap disposed on a surface of the susceptor plate. The cap may have electrodes embedded within it. The susceptor plate may have heating elements embedded within it. The cap may be separated from the susceptor plate by an air gap formed by a plurality of dielectric spacers. The plurality of dielectric spacers may be sized for minimal contact on the cap.

According to one aspect, an apparatus comprises: a susceptor plate comprising a first surface and a second surface; a cap removably disposed on the first surface of the susceptor plate; an air gap between the first surface of the susceptor plate and the cap; a plurality of electrodes embedded within the cap; a first electrical interconnect embedded within the susceptor plate and extending through the first and second surfaces; and a second electrical interconnect configured to electrically connect the plurality of electrodes to the first electrical interconnect.

In one embodiment, the susceptor plate is formed from a metal material.

In one embodiment, the cap is formed from a ceramic material.

In one embodiment, the apparatus further comprises a heating element embedded within the susceptor plate.

In one embodiment, the apparatus further comprises a shaft coupled to the second surface of the susceptor plate, wherein the shaft comprises a hollow interior.

In one embodiment, the first electrical interconnect extends into the hollow interior of the shaft.

In one embodiment, the susceptor plate is formed from a ceramic material.

In one embodiment, the apparatus further comprises a plurality of dielectric spacers arranged between the first surface of the susceptor plate and the cap, wherein the dielectric spacers form an air gap between the first surface of the susceptor plate and the cap.

In one embodiment, the susceptor plate further comprises a plurality of through-holes extending from the first surface to the second surface, wherein each through-hole is fluidly connected to an inert gas supply.

In yet another aspect, an apparatus comprises: a susceptor plate comprising a first surface and a second surface; a cap removably disposed on the first surface of the susceptor plate; a plurality of dielectric spacers arranged between the first surface of the susceptor plate and the cap, wherein the dielectric spacers form an air gap between the first surface of the susceptor plate and the cap; a plurality of electrodes embedded within the cap; an electrical port embedded within the susceptor plate; and an electrical plug connected to the plurality of electrodes, wherein the electrical plug is configured to electrically connect to the first electrical port.

In one embodiment, the susceptor plate is formed from a metal material.

In one embodiment, the cap is formed from a ceramic material.

In one embodiment, the apparatus further comprises a heating element embedded within the susceptor plate.

In one embodiment, the apparatus further comprises a shaft coupled to the second surface of the susceptor plate, wherein the shaft comprises a hollow interior.

In one embodiment, at least a portion of the second electrical port is encapsulated with an insulating material.

In yet another aspect, a system comprises: a reaction chamber comprising an interior space; a susceptor assembly disposed within the interior space, and comprising: a susceptor plate formed from a metal material and comprising a first surface and a second surface; a cap disposed on the susceptor plate and formed from a ceramic material; a plurality of spacers arranged between the first surface of the susceptor plate and the cap, wherein the spacers form an air gap between the first surface of the susceptor plate and the cap; a plurality of electrodes embedded within the cap; and an electrical interconnect extending through the first and second surfaces of the susceptor plate, wherein the electrical interconnect is configured to electrically connect to the plurality of electrodes.

In one embodiment, the susceptor plate further comprises a through-hole extending from the first surface to the second surface, and wherein the electrical interconnect is disposed within the through-hole.

In one embodiment, each spacer has a width no greater than 1 mm.

In one embodiment, the system further comprises a heating element embedded within the susceptor plate.

In one embodiment, the susceptor plate further comprises a plurality of through-holes extending from the first surface to the second surface, wherein each through-hole is fluidly connected to an inert gas supply.

### BRIEF DESCRIPTION OF THE DRAWING FIGURES

A more complete understanding of the present technology may be derived by referring to the detailed description when considered in connection with the following illustrative figures. In the following figures, like reference numbers refer to similar elements and steps throughout the figures.

FIG. 1 is a block diagram of a system in accordance with various embodiments of the present technology;

FIG. 2 representatively illustrates a cross-sectional view of a susceptor assembly in accordance with various embodiments of the present technology;

FIG. 3 representatively illustrates a top view of a susceptor plate in accordance with various embodiments of the present technology;

FIG. 4A representatively illustrates a cross-sectional view of a dielectric spacer in accordance with various embodiments of the present technology;

FIG. 4B representatively illustrates an alternative cross-sectional view of a dielectric spacer in accordance with various embodiments of the present technology;

FIG. 5 representatively illustrates a portion of the susceptor assembly in accordance with various embodiments of the present technology;

FIG. 6 representatively illustrates an electrical interconnect in the susceptor assembly in accordance with various embodiments of the present technology;

FIG. 7 representatively illustrates an alternative electrical interconnect in the susceptor assembly in accordance with various embodiments of the present technology; and

FIG. 8 representatively illustrates an alternative electrical interconnect in the susceptor assembly in accordance with various embodiments of the present technology.

### DETAILED DESCRIPTION OF EXEMPLARY EMBODIMENTS

The present technology may be described in terms of functional block components and various processing steps. Such functional blocks may be realized by any number of components configured to perform the specified functions and achieve the various results. For example, the present technology may employ various reaction chambers, lift pins, processors/control units, heating elements, electrodes, and gas delivery systems.

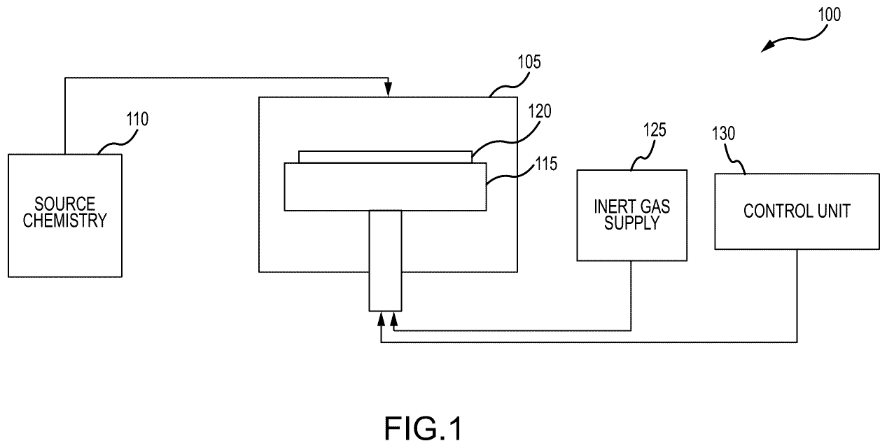

Referring to FIG. 1, an exemplary system 100 may comprise a reaction chamber 105, a source chemistry vessel 110, an inert gas supply 125, and a control unit 130. The reaction chamber 105 may be used to deposit a film on a substrate, such as a wafer 120. The reaction chamber 105 may comprise a plurality of sidewalls and a bottom surface that form an interior space.

The source chemistry vessel 110 may be configured to contain a solid or liquid chemistry. In various embodiments, the vessel 110 may be configured to heat or sublimate the chemistry to a gas form. The gas may flow into the reaction chamber 105. For example, the system 100 may comprise a gas line assembly (not shown) configured to flow the gas into the reaction chamber 105 at a desired flow rate.

In various embodiments, the system 100 may further comprise a showerhead assembly (not shown) for delivering and distributing a gas into the reaction chamber 105. For example, the showerhead may comprise a plurality of through holes configured to flow the gas into the interior space of the reaction chamber 105. The showerhead assembly may be arranged above the reaction chamber 105 and enclose the interior space of the reaction chamber 105.

In various embodiments, the inert gas supply 125 may be configured to contain an inert gas, such as argon or nitrogen. The inert gas supply 125 may comprise a vessel, capsule, or other suitable container. The inert gas supply 125 may be pressurized or unpressurized.

In various embodiments, the inert gas supply 125 may be fluidly connected to the susceptor assembly 115. For example, the inert gas supply 125 may be coupled to the susceptor assembly 115 with a tube, gas line, or other suitable hollow connector.

In various embodiments, the control unit 130 may be configured to operate various aspects of the susceptor assembly 115, control operation of valves, and supply power to the aspects of the susceptor assembly 115. For example, the control unit 130 may generate various control signals based on a desired operation of the susceptor assembly 115. The control unit 130 may comprise a processor, memory, and/or any other system or device suitable for generating control signals and supplying power.

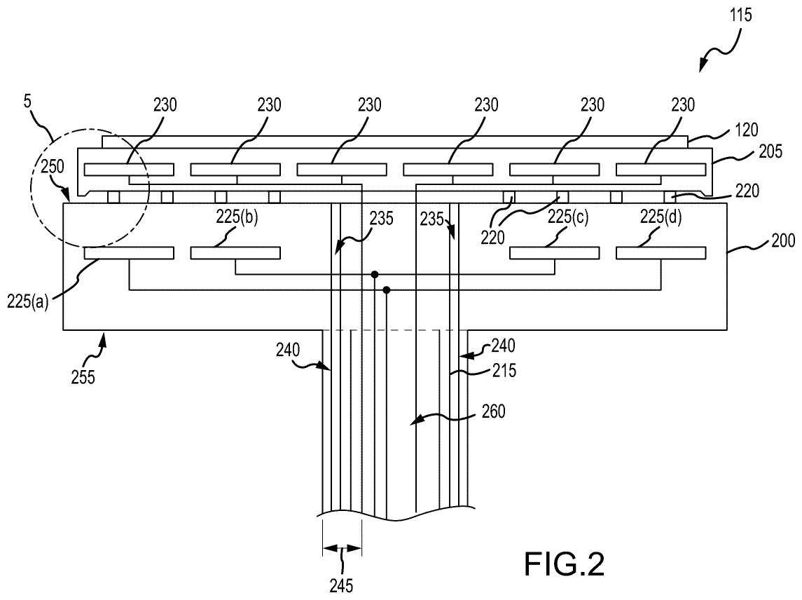

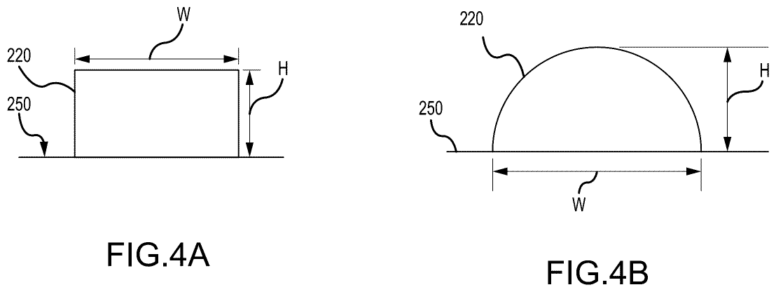

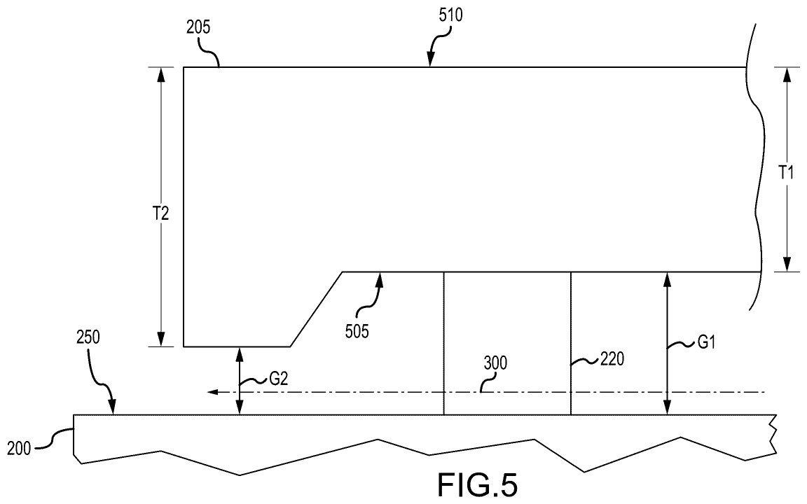

In various embodiments, and referring to FIGS. 2-5, the susceptor assembly 115 may be configured to support the wafer 120 during processing/film deposition and may be disposed within the interior space of the reaction chamber 105. In an exemplary embodiment, the susceptor assembly 115 may comprise a susceptor plate 200, a pedestal 215, and a cap 205.

In various embodiments, the susceptor assembly 115 may be configured to provide an electrostatic chucking function.

In some embodiments, the susceptor assembly 115 may be configured to move up and down. Alternatively, the susceptor assembly 115 may be in a fixed position.

The susceptor plate 200 may comprise a first surface 250 and an opposing second surface 255. For example, the first and second surfaces 250, 255 may be in parallel with each other. In one embodiment, the susceptor plate 200 may be formed from a ceramic material, such as aluminum nitride, alumina, silicon carbide (SiC), silicon nitride (SiN). In other embodiments, the susceptor plate 200 may be formed from a metal material, such as a stainless steel, Hastelloy C22, or any other suitable high temperature metal or metal alloy.

In various embodiments, the susceptor plate 200 may comprise a plurality of heating elements 225 embedded within the susceptor plate 200. The heating elements 225 may be utilized to control a temperature of the susceptor plate 200. The heating elements 225 may comprise any device suitable for generating heat. The heating elements 225 may be arranged in any desired pattern. In some embodiments, the heating elements 225 may be arranged to provide a plurality of heating zones. For example, the heating elements 225 may be arranged in a pattern that provides a first temperature near a center of the susceptor plate 200 and a second temperature near the outer edges of the susceptor plate 200, wherein the first temperature is different from the second temperature. For example, a first subset of the heating elements (e.g., 225(b) and 225(c)) may be electrically connected together and a second subset of the heating elements (e.g., 225(a) and 225(d)) may be electrically connected together. The first and second subsets may be electrically isolated from each other and, therefore, the first subset of heating elements may be operated independently from the second subset of the heating elements. For example, heating elements 225(b) and 225(c) may be operated together and at a first temperature, and heating elements 225(a) and 225(d) may be operated together and at a second temperature.

In an exemplary embodiment, the susceptor plate 200 may further comprise a plurality of through-holes 235 that extend from the first surface 250 to the second surface 250. The through-holes 235 may provide a flow path for a gas, such as the inert gas from the inert gas supply 125. In an exemplary embodiment, the through-holes 235 are unobstructed by other elements or features. In other words, the through-holes 235 are open to allow a gas to flow through easily.

In various embodiments, the dielectric spacers 220 may be disposed between the susceptor plate 200 and the cap 205. In particular, the dielectric spacers 220 may be disposed directly on the first surface 250 of the susceptor plate 200. The dielectric spacers 220 may be formed from a material having a high contact resistance, such as materials from the silicate family, zirconia, beryllium carbide (BeC), zirconium carbide (ZrC), silicon carbide, silicon nitride, or the like, to prevent current leakage from the cap 205 to the susceptor plate 200.

In various embodiments, the dielectric spacers 220 may have any suitable shape, for example, cubic shaped or hemispherical. In various embodiments, the dielectric spacer 220 may have a height H of 1 mm or less and a width W (or diameter) of 1 mm or less. In various embodiments, the total area covered by the dielectric spacers 220 is less than 1% of the total surface area of the first surface 250 of the susceptor plate 200.

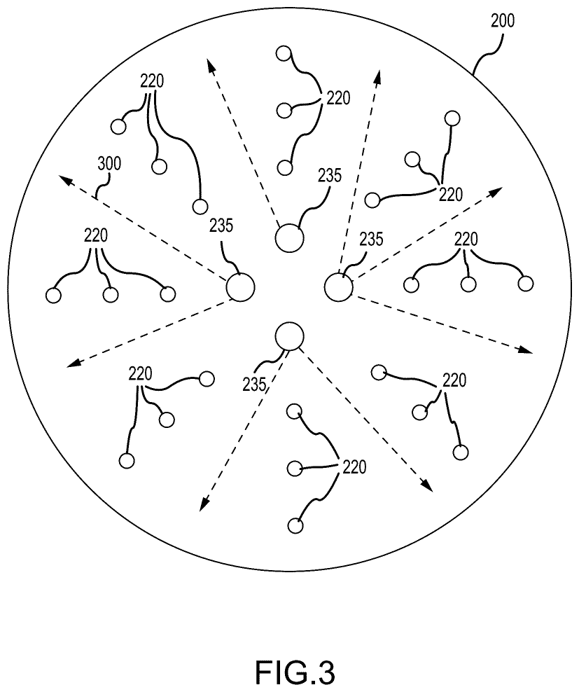

In various embodiments, the dielectric spacers 220 may be arranged in any suitable pattern to allow gas to flow from the center of the susceptor plate 200 to the outer edge of the susceptor plate 200. For example, the dielectric spacers 220 may be arranged as illustrated in FIG. 3, such that flow paths 300 extend radially outward to the edge of the susceptor plate 200.

In various embodiments, the cap 205 may be disposed adjacent to the first surface 250 of the susceptor plate 200. The cap 205 may comprise a top surface 510 and a bottom surface 505. In various embodiments, the cap 205 may be removable from the susceptor plate 200. For example, the cap 205 may rest on the dielectric spacers 220 or it may be removably coupled by way of a separable electrical interconnect.

In various embodiments, the cap 205 may have a first thickness T1 at a center region and a second thickness T2 on an outer region that surrounds the center region. Accordingly, the bottom surface 505 of the cap 205 may have a recessed area. In other words, the bottom surface 505 of the cap 205 may not be planar. In the present case, the bottom surface 505 may comprise planar surfaces connected by a sloped surface.

In alternative embodiments, the bottom surface 505 of the cap 205 is planar. In this case, the cap 205 will have a uniform thickness across its entire area.

In various embodiments, the bottom surface 505 of the cap 205 may be separated from the first surface 250 of the susceptor plate 200 by a first air gap G1 and a second air gap G2. The first air gap G1 is the gap between the bottom surface of the cap 205, where the cap 205 has the first thickness T1, and the first surface 250 of the susceptor plate 200. The first air gap G1 may be formed by way of the dielectric spacers 220. Accordingly, a height of the air gap may be equal to the height of the dielectric spacer.

The second air gap G2 is the gap between the bottom surface of the cap 205, where the cap 205 has the second thickness T2, and the first surface 250 of the susceptor plate 200. Accordingly, the height of the second air gap G2 may vary based on the value of the second thickness T2.

In an exemplary embodiment, the cap 205 may comprise a plurality of electrodes 230. The plurality of electrodes 230 may be configured to provide an electrostatic chucking function. Accordingly, the plurality of electrodes may be connected to a power supply or voltage source.

In various embodiments, the cap 205 may be formed from a ceramic material having a high resistivity, such as aluminum nitride, alumina, silicon carbide (SiC), silicon nitride (SiN).

In various embodiments, the cap 205 may comprise a recessed pocket (not shown) on a top surface 500 of the cap 205. The recessed pocket may be sized to accommodate a wafer within the recessed pocket.

The second thickness T2 may be greater than the first thickness T1. Accordingly, the air gap G1 may be greater than the air gap G2. The second thickness T2 of the cap 205 may be in the range of 3 mm to 7 mm. The first thickness T1 may be in the range of 3 mm to 5 mm.

In various embodiments, the pedestal 215 may be coupled to the second surface 255 of the susceptor plate 200. The pedestal 215 may comprise an outer sidewall 270 and an inner sidewall 275. The inner sidewall 275 may be spaced from the outer sidewall 270 by a gap having a width 245, wherein the inner sidewall 275 and the outer sidewall 270 form an outer hollow region. The inner sidewall 275 may also form a center hollow region 260. The center hollow region 260 may be used to house or otherwise secure electrical interconnects, such as the electrical interconnects connected to the heating elements 225 and/or the electrodes 230.

In various embodiments, the pedestal 215 may further comprise a plurality of gas lines 240 to connect to the through holes 235 in the susceptor plate 200. The gas lines 240 may be configured to provide a flow path for a gas, such as the inert gas from the inert gas supply 125. The gas lines 240 may be formed from a metal material or any other suitable material. In an exemplary embodiment, the gas lines 240 may be arranged within the outer hollow region, between the inner sidewall 275 and the outer sidewall 270. Alternatively, the gas lines 240 may be disposed within the center hollow region 260.

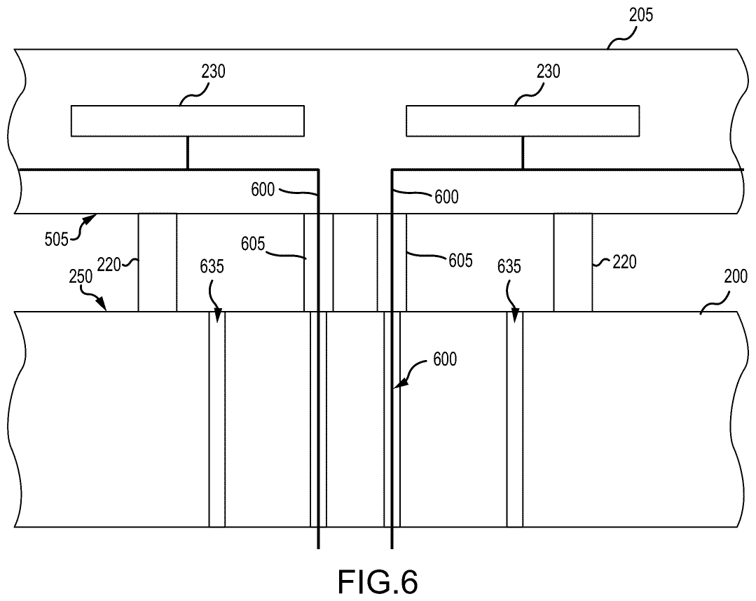

Embodiments of the present technology may utilize any suitable electrical connection to electrically connect the electrodes 230 to the control unit 130. In one embodiment, an referring to FIG. 6, an electrical wire 600 may be used to connect to the desired electrodes 230. In the present case, the wire 600 may extend out through the bottom surface 505 of the cap 205, through the air gap G1, through the susceptor plate 200 and through the pedestal 215. In the present case, the electrical wire 600 may be one continuous wire.

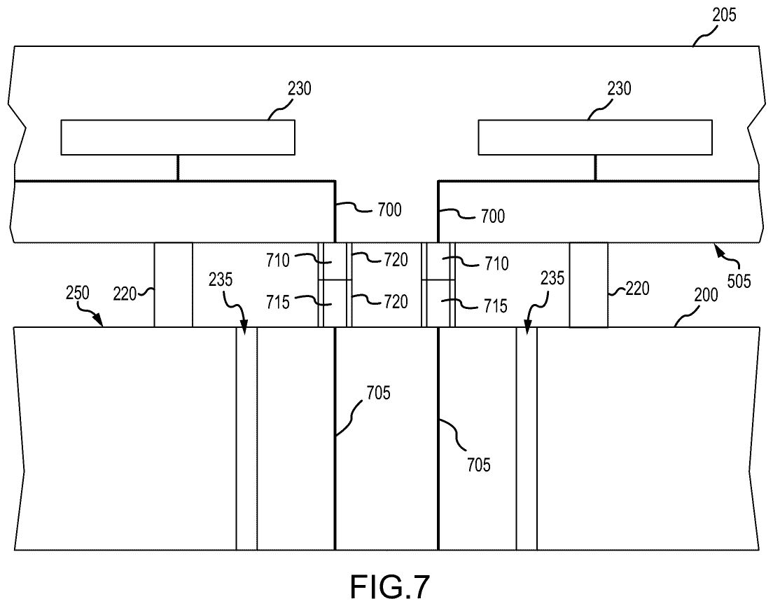

In an alternative embodiment, and referring to FIG. 7, the electrical connection may comprise contact pads to form an electrical connection between the electrodes 230 in the cap 205 and the susceptor plate 200. In an exemplary embodiment, the cap 205 may comprise electrical wires 700 that connect to the electrodes 230 and extend to the bottom surface 505 and a first contact pad 710, disposed at the bottom surface 505, electrically connected to the wire 700. The contact pad 710 may be encapsulated by an electrically insulating material 720. In the present case, the susceptor plate 200 may comprise wires 705 that extend through the susceptor plate 200 and are connected to a second contact pad 715 at the first surface 250 of the susceptor plate 200. The first and second contact pads 710, 715 align to form an electrical connection. The wires 705 in the susceptor plate 200 may extend through the pedestal 215 and connect to the control unit 130.

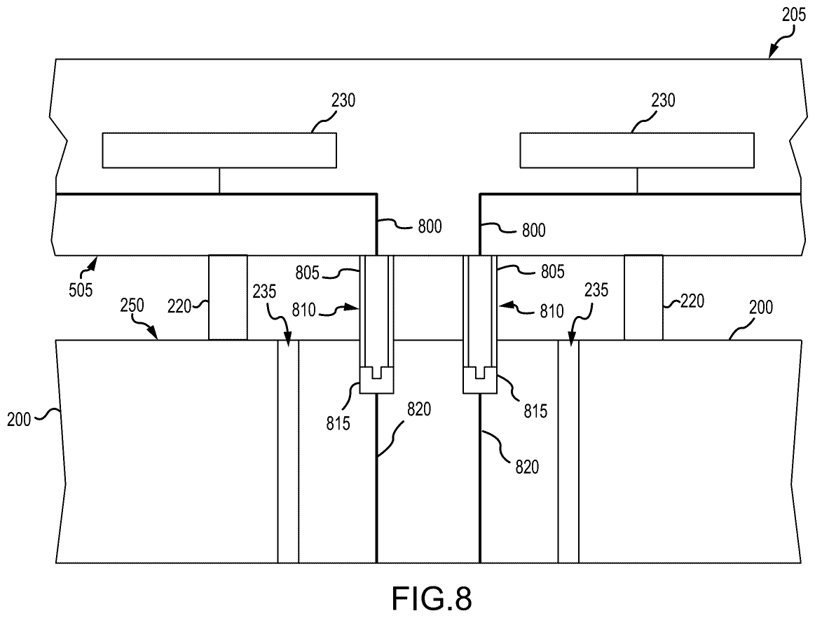

In an alternative embodiment, and referring to FIG. 8, the electrical connection may comprise a plug 805 and plug port 815 to form an electrical connection between the electrodes 230 and the susceptor plate 200. In an exemplary embodiment, the cap 205 may comprise electrical wires 800 that electrically connect the electrodes 230 to a plug 805. The plug 805 may be encapsulated by an electrically insulating material 805. The susceptor plate 200 may comprise the plug port 815. The plug port 815 may be embedded within the susceptor plate 200. In an exemplary embodiment, the plug 805 is arranged to vertically align with and electrically connect with or otherwise mate with the plug port 815. The plug port 815 may be electrically connected to the control unit 130 with electrical wires 820 to provide power to the electrodes 230.

In various embodiments, the system 100 may further comprise a plurality of lift pins (not shown). Each lift pin may be disposed within a respective through-hole (not shown) that extends through the susceptor plate 200 and a respective through-hole (not shown) that extends through the cap 205. The through-hole is the cap 205 aligns with the through-hole in the susceptor plate 200. Accordingly, one lift pin extends all the way through the susceptor plate 200 and the cap 205. The lift pins may be formed from a ceramic material, a metal material, or any suitable material.

In operation, and referring to FIGS. 1-3, the susceptor assembly 115 may provide electrostatic chucking and/or temperature control. For example, the control unit 130 may transmit control signals and/or power to the electrodes 230 to form an electric field. The control unit 130 may also transmit control signals and/or power to the heating elements 225 to heat the susceptor plate 200 to a desired temperature.

The control unit 130 may also control gas flow in the system 100. For example, the control unit 130 may control a valve (not shown) arranged between the inert gas supply 125 and the susceptor assembly 115. The valve may control flow of the inert gas from the inert gas supply 125 to the pedestal 215. For example, the valve may be connected to the gas lines 240 disposed within the pedestal 215. When the valve is open, inert gas from the inert gas supply 125 flows through the gas lines 240 and through the through-holes 235. The gas exists the through-holes 235 and flows through the gap between the susceptor plate 200 and the cap 205. As illustrated in FIG. 3, the gas may flow radially outward to the edges of the susceptor plate 200. This radial flow pattern may prevent chemistry from depositing on the bottom surface 505 of the cap 205. The gas flow may also provide improved temperature control, heat transfer, and/or thermal uniformity by creating a convection-like heating of the cap 205. The gas flow may also prevent electrical interface oxidation.

In the foregoing description, the technology has been described with reference to specific exemplary embodiments. The particular implementations shown and described are illustrative of the technology and its best mode and are not intended to otherwise limit the scope of the present technology in any way. Indeed, for the sake of brevity, conventional manufacturing, connection, preparation, and other functional aspects of the method and system may not be described in detail. Furthermore, the connecting lines shown in the various figures are intended to represent exemplary functional relationships and/or steps between the various elements. Many alternative or additional functional relationships or physical connections may be present in a practical system.

The technology has been described with reference to specific exemplary embodiments. Various modifications and changes, however, may be made without departing from the scope of the present technology. The description and figures are to be regarded in an illustrative manner, rather than a restrictive one and all such modifications are intended to be included within the scope of the present technology. Accordingly, the scope of the technology should be determined by the generic embodiments described and their legal equivalents rather than by merely the specific examples described above. For example, the steps recited in any method or process embodiment may be executed in any order, unless otherwise expressly specified, and are not limited to the explicit order presented in the specific examples. Additionally, the components and/or elements recited in any apparatus embodiment may be assembled or otherwise operationally configured in a variety of permutations to produce substantially the same result as the present technology and are accordingly not limited to the specific configuration recited in the specific examples.

Benefits, other advantages and solutions to problems have been described above with regard to particular embodiments. Any benefit, advantage, solution to problems or any element that may cause any particular benefit, advantage or solution to occur or to become more pronounced, however, is not to be construed as a critical, required or essential feature or component.

The terms “comprises”, “comprising”, or any variation thereof, are intended to reference a non-exclusive inclusion, such that a process, method, article, composition or apparatus that comprises a list of elements does not include only those elements recited, but may also include other elements not expressly listed or inherent to such process, method, article, composition or apparatus. Other combinations and/or modifications of the above-described structures, arrangements, applications, proportions, elements, materials or components used in the practice of the present technology, in addition to those not specifically recited, may be varied or otherwise particularly adapted to specific environments, manufacturing specifications, design parameters or other operating requirements without departing from the general principles of the same.

The present technology has been described above with reference to an exemplary embodiment. However, changes and modifications may be made to the exemplary embodiment without departing from the scope of the present technology. These and other changes or modifications are intended to be included within the scope of the present technology, as expressed in the following claims.

What is claimed is:

1. An apparatus, comprising:
a susceptor plate comprising a first surface and a second surface;
a cap removably disposed on the first surface of the susceptor plate;
an air gap between the first surface of the susceptor plate and the cap;
a plurality of electrodes embedded within the cap;
a first electrical interconnect embedded within the susceptor plate and extending through the first and second surfaces; and
a second electrical interconnect configured to electrically connect the plurality of electrodes to the first electrical interconnect.

2. The apparatus according to claim 1, wherein the susceptor plate is formed from a metal material.

3. The apparatus according to claim 1, wherein the cap is formed from a ceramic material.

4. The apparatus according to claim 1, further comprising a heating element embedded within the susceptor plate.

5. The apparatus according to claim 1, further comprising a shaft coupled to the second surface of the susceptor plate, wherein the shaft comprises a hollow interior.

6. The apparatus according to claim 5, wherein the first electrical interconnect extends into the hollow interior of the shaft.

7. The apparatus according to claim 1, wherein the susceptor plate is formed from a ceramic material.

8. The apparatus according to claim 1, further comprising a plurality of dielectric spacers arranged between the first surface of the susceptor plate and the cap, wherein the dielectric spacers form an air gap between the first surface of the susceptor plate and the cap.

9. The apparatus according to claim 1, wherein the susceptor plate further comprises a plurality of through-holes extending from the first surface to the second surface, wherein each through-hole is fluidly connected to an inert gas supply.

10. An apparatus, comprising:
a susceptor plate comprising a first surface and a second surface;
a cap removably disposed on the first surface of the susceptor plate;
a plurality of dielectric spacers arranged between the first surface of the susceptor plate and the cap, wherein the dielectric spacers form an air gap between the first surface of the susceptor plate and the cap;
a plurality of electrodes embedded within the cap;
an electrical port embedded within the susceptor plate; and
a electrical plug connected to the plurality of electrodes, wherein the electrical plug is configured to electrically connect to the electrical port.

11. The apparatus according to claim 10, wherein the susceptor plate is formed from a metal material.

12. The apparatus according to claim 10, wherein the cap is formed from a ceramic material.

13. The apparatus according to claim 10, further comprising a heating element embedded within the susceptor plate.

14. The apparatus according to claim 10, further comprising a shaft coupled to the second surface of the susceptor plate, wherein the shaft comprises a hollow interior.

15. The apparatus according to claim 10, wherein at least a portion of the electrical plug is encapsulated with an insulating material.

16. A system, comprising:
a reaction chamber comprising an interior space;
a susceptor assembly disposed within the interior space, and comprising:
a susceptor plate formed from a metal material and comprising a first surface and a second surface;
a cap disposed on the susceptor plate and formed from a ceramic material;
a plurality of spacers arranged between the first surface of the susceptor plate and the cap, wherein the spacers form an air gap between the first surface of the susceptor plate and the cap;
a plurality of electrodes embedded within the cap; and
an electrical interconnect extending through the first and second surfaces of the susceptor plate, wherein the electrical interconnect is configured to electrically connect to the plurality of electrodes.

17. The system according to claim 16, wherein the susceptor plate further comprises a through-hole extending from the first surface to the second surface, and wherein the electrical interconnect is disposed within the through-hole.

18. The system according to claim 16, wherein each spacer has a width no greater than 1 mm.

19. The system according to claim 16, further comprising a heating element embedded within the susceptor plate.

20. The system according to claim 16, wherein the susceptor plate further comprises a plurality of through-holes extending from the first surface to the second surface, wherein each through-hole is fluidly connected to an inert gas supply.
